(19) United States
(12) Patent Application Publication
(10) Pub. No.: US 2025/0351553 A1
(43) Pub. Date: Nov. 13, 2025

(54) SEMICONDUCTOR DEVICE

(71) Applicant: FUJI ELECTRIC CO., LTD., Kanagawa (JP)

(72) Inventors: Toshiyuki MATSUI, Matsumoto-city (JP); Tatsuya NAITO, Matsumoto-city (JP); Seiji NOGUCHI, Matsumoto-city (JP); Takuya YAMADA, Matsumoto-city (JP); Masaaki FURUKAWA, Matsumoto-city (JP); Ryutaro HAMASAKI, Matsumoto-city (JP); Yoshihiro IKURA, Matsumoto-city (JP); Shuhei TATEMICHI, Matsumoto-city (JP)

(21) Appl. No.: 19/277,332

(22) Filed: Jul. 22, 2025

Related U.S. Application Data
(63) Continuation of application No. PCT/JP2024/024954, filed on Jul. 10, 2024.

(30) Foreign Application Priority Data
Aug. 7, 2023 (JP) 2023-128871

(51) Int. Cl. H10D 84/00

(52) U.S. Cl. CPC H10D 84/161

(57) ABSTRACT

The present invention provides a semiconductor device including a transistor portion and a diode portion, in which the transistor portion has a first gate trench portion which is provided to be closest to the diode portion, and a first mesa portion which is in contact with the first gate trench portion, and which is provided between the first gate trench portion and the diode portion, below the first gate trench portion, a first floating region is provided, and the first mesa portion has an uncovered region which does not overlap with the first floating region.

The contents of the following patent application(s) are incorporated herein by reference:
NO. 2023-128871 filed in JP on Aug. 7, 2023
NO. PCT/JP2024/024954 filed in WO on Jul. 10, 2024.

### BACKGROUND

### 1. Technical Field

The present invention relates to a semiconductor device.

### 2. Related Art

In the related art, a semiconductor device provided with a transistor such as an insulated gate bipolar transistor (IGBT) is known (refer to Patent Documents 1 to 4, for example).

### RELATED ART DOCUMENTS

### Patent Documents

Patent Document 1: Japanese Patent No. 6472714
Patent Document 2: Japanese Patent No. 4456013
Patent Document 3: Japanese Patent Application Publication No. 2020-21941
Patent Document 4: Japanese Patent Application Publication No. 2010-232627

### BRIEF DESCRIPTION OF THE DRAWINGS

FIG. 1 is a top plan view showing an example of a semiconductor device 100 according to one embodiment of the present invention.

FIG. 2 shows an enlarged view of a region D in FIG. 1.

FIG. 3 is a view showing an example of a cross section e-e in FIG. 2.

FIG. 4 is a diagram showing an arrangement example of a floating region 202 in a top view.

FIG. 5 is a diagram showing another arrangement example of the floating region 202 in the top view.

FIG. 6 is a view showing another example of the cross section e-e.

FIG. 7 is a view showing another example of the cross section e-e.

FIG. 8 is a top plan view showing an example of a transition region 92.

FIG. 9 is a view showing an example of a cross section f-f in FIG. 8.

FIG. 10 is an XZ cross section showing another structure example of a boundary region 90 and a diode portion 80.

FIG. 11 is a diagram showing a collector voltage-collector current characteristic, in an Example and a reference example.

FIG. 12 is a diagram showing a trade-off characteristic between a turn-on loss and a reverse recovery dV/dt in a reference example and an Example.

### DESCRIPTION OF EXEMPLARY EMBODIMENTS

Hereinafter, the present invention will be described through embodiments of the invention, but the following embodiments do not limit the invention according to claims. In addition, not all combinations of features described in the embodiments are essential to a solution of the invention.

As used herein, one side in a direction parallel to a depth direction of a semiconductor substrate is referred to as an “upper” side and another side is referred to as a “lower” side. One surface of two principal surfaces of a substrate, a layer, or another member is referred to as an upper surface, and another surface is referred to as a lower surface. “Upper” and “lower” directions are not limited to a direction of gravity, or a direction in which a semiconductor device is mounted.

In the present specification, technical matters may be described by using orthogonal coordinate axes of an X axis, a Y axis, and a Z axis. The orthogonal coordinate axes merely specify relative positions of components, and do not limit a particular direction. For example, the Z axis is not limited to indicating a height direction with respect to the ground. It should be noted that a +Z axis direction and a −Z axis direction are directions opposite to each other. If a Z axis direction is described without describing the signs, it means that the direction is parallel to the +Z axis and the −Z axis.

In the present specification, orthogonal axes parallel to the upper surface and the lower surface of the semiconductor substrate are referred to as the X axis and the Y axis. In addition, an axis perpendicular to the upper surface and the lower surface of the semiconductor substrate is referred to as the Z axis. In the present specification, the direction of the Z axis may be referred to as a depth direction. In addition, in the present specification, a direction parallel to the upper surface and the lower surface of the semiconductor substrate may be referred to as a horizontal direction, including an X axis direction and a Y axis direction.

A region from the center of the semiconductor substrate in the depth direction to the upper surface of the semiconductor substrate may be referred to as an upper surface side. Similarly, a region from the center of the semiconductor substrate in the depth direction to the lower surface of the semiconductor substrate may be referred to as a lower surface side.

In the present specification, a case where a term such as “same” or “equal” is mentioned may include a case where an error due to a variation in manufacturing or the like is included. The error is, for example, within 10%.

In the present specification, a conductivity type of a doping region doped with impurities is described as a P type or an N type. In the present specification, the impurities may particularly mean either donors of the N type or acceptors of the P type, and may be described as dopants. In the present specification, doping means introducing the donor or the acceptor into the semiconductor substrate and turning it into a semiconductor presenting a conductivity type of the N type or a semiconductor presenting a conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is ND and the acceptor concentration is NA, the net doping concentration at any position is given as ND-NA. In the present specification, the net doping concentration may be simply described as the doping concentration.

In the present specification, a description of a P+ type or an N+ type means a higher doping concentration than that of the P type or the N type, and a description of a P-type or an N-type means a lower doping concentration than that of the P type or the N type. In addition, in the present specification, a description of a P++ type or an N++ type means a higher doping concentration than that of the P+ type or the N+ type. In the present specification, a unit system is an SI unit system unless otherwise noted. Although a unit of a length may be expressed in cm, various calculations may be performed after conversion to meters (m).

A chemical concentration in the present specification refers to an atomic density of an impurity measured regardless of an electrical activation state. The chemical concentration can be measured by, for example, secondary ion mass spectrometry (SIMS). The net doping concentration described above can be measured by capacitance-voltage profiling (CV method). In addition, a carrier concentration measured by spreading resistance profiling (SRP method) may be set as the net doping concentration. The carrier concentration measured by the CV method or the SRP method may be a value in a thermal equilibrium state. In addition, in a region of the N type, the donor concentration is sufficiently higher than the acceptor concentration, and thus the carrier concentration of the region may be set as the donor concentration. Similarly, in a region of the P type, the carrier concentration of the region may be set as the acceptor concentration. In the present specification, the doping concentration of the N type region may be referred to as the donor concentration, and the doping concentration of the P type region may be referred to as the acceptor concentration.

When a concentration distribution of the donor, acceptor, or net doping has a peak in a region, a value of the peak may be defined as the concentration of the donor, acceptor, or net doping in the region. In a case where the concentration of the donor, acceptor or net doping is substantially uniform in a region, or the like, an average donor, acceptor or net doping concentration in the region may be defined as a donor, acceptor or net doping concentration. In the present specification, atoms/cm³ or /cm³ is used to express a concentration per unit volume. This unit is used for the donor or acceptor concentration or the chemical concentration in the semiconductor substrate. A notation of atoms may be omitted.

The carrier concentration measured by the SRP method may be lower than the concentration of the donor or the acceptor. In a range where a current flows when a spreading resistance is measured, carrier mobility of the semiconductor substrate may be lower than a value in a crystalline state. The decrease in the carrier mobility occurs when carriers are scattered due to disorder (disorder) of a crystal structure due to a lattice defect or the like.

The concentration of the donor or the acceptor calculated from the carrier concentration measured by the CV method or the SRP method may be lower than a chemical concentration of an element indicating the donor or the acceptor. As an example, in a silicon semiconductor, a donor concentration of phosphorous or arsenic serving as a donor, or an acceptor concentration of boron (boron) serving as an acceptor is approximately 99% of chemical concentrations of these. On the other hand, in the silicon semiconductor, a donor concentration of hydrogen serving as a donor is approximately 0.1% to 10% of a chemical concentration of hydrogen.

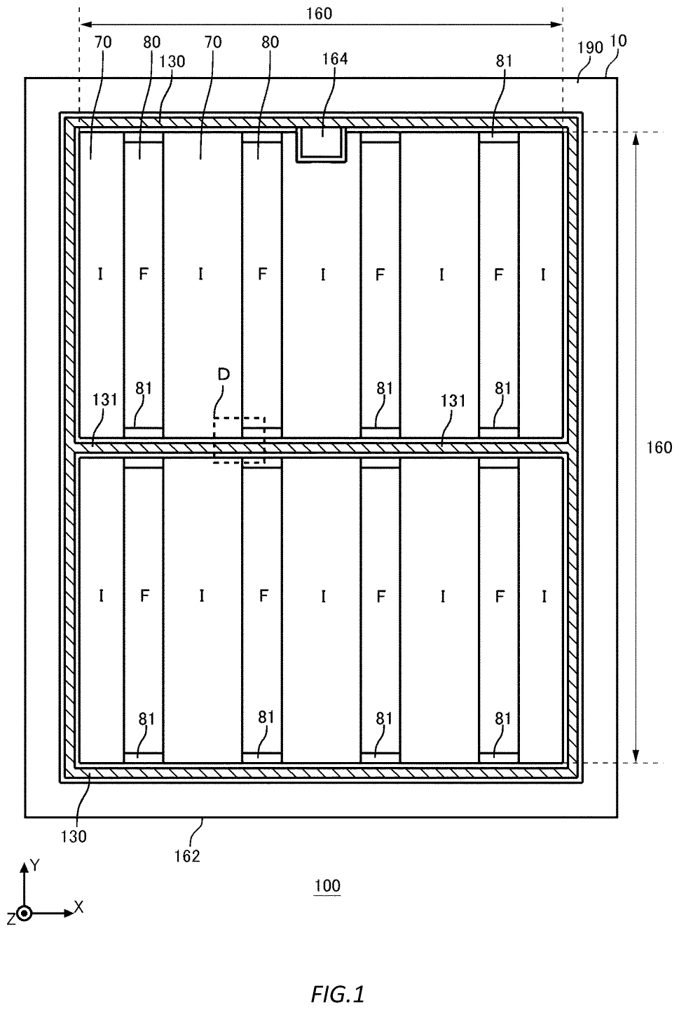

FIG. 1 is a top plan view showing an example of a semiconductor device 100 according to one embodiment of the present invention. FIG. 1 shows a position of each member projected onto an upper surface of a semiconductor substrate 10. In FIG. 1, only some members of the semiconductor device 100 are shown, and illustrations of some members are omitted.

The semiconductor device 100 includes the semiconductor substrate 10. The semiconductor substrate 10 is a substrate which is formed of a semiconductor material. As an example, the semiconductor substrate 10 is a silicon substrate. The semiconductor substrate 10 has an end side 162 in a top view. When simply referred to as the top view in the present specification, it means that the semiconductor substrate 10 is viewed from an upper surface side. The semiconductor substrate 10 in the present example has two sets of end sides 162 opposite to each other in the top view. In FIG. 1, the X axis and the Y axis are parallel to any of the end sides 162. In addition, the Z axis is perpendicular to the upper surface of the semiconductor substrate 10.

The semiconductor substrate 10 is provided with an active portion 160. The active portion 160 is a region where a main current flows in a depth direction between the upper surface and a lower surface of the semiconductor substrate 10 when the semiconductor device 100 operates. An emitter electrode is provided above the active portion 160, but illustration thereof is omitted in FIG. 1. The active portion 160 may refer to a region which overlaps with the emitter electrode in the top view. In addition, a region sandwiched between active portions 160 in the top view may also be included in the active portion 160.

The active portion 160 is provided with transistor portions 70 including transistor elements such as an Insulated Gate Bipolar Transistor (IGBT). The active portion 160 may be further provided with diode portions 80 including diode elements such as a freewheeling diode (FWD). In the example shown in FIG. 1, transistor portions 70 and diode portions 80 are alternately arranged along a predetermined array direction (the X axis direction in the present example) at the upper surface of the semiconductor substrate 10. The semiconductor device 100 in the present example is a reverse conduction type IGBT (RC-IGBT).

In FIG. 1, a region where each of the transistor portions 70 is arranged is indicated by a symbol “I”, and a region where each of the diode portions 80 is arranged is indicated by a symbol “F”. In the present specification, a direction perpendicular to the array direction in the top view may be referred to as an extension direction (the Y axis direction in FIG. 1). Each of the transistor portions 70 and the diode portions 80 may have a longitudinal length in the extension direction. In other words, a length of the transistor portion 70 in the Y axis direction is greater than a width in the X axis direction. Similarly, a length of the diode portion 80 in the Y axis direction is greater than a width in the X axis direction. The extension directions of the transistor portion 70 and the diode portion 80, and a longitudinal direction of each trench portion described below may be the same.

Each of the diode portions 80 includes a cathode region of the N+ type in a region in contact with the lower surface of the semiconductor substrate 10. In the present specification, a region where the cathode region is provided is referred to as the diode portion 80. In other words, the diode portion 80 is a region which overlaps with the cathode region in the top view. At the lower surface of the semiconductor substrate 10, a collector region of the P+ type may be provided in a region other than the cathode region. In the present specification, the diode portion 80 may also include an extension region 81 where the diode portion 80 extends to a gate runner described below in the Y axis direction. The collector region is provided at a lower surface of the extension region 81.

The transistor portion 70 has the collector region of the P+ type in a region in contact with the lower surface of the semiconductor substrate 10. In addition, in the transistor portion 70, an emitter region of the N type, a base region of the P type, and a gate structure having a gate conductive portion and a gate dielectric film are periodically arranged at the upper surface side of the semiconductor substrate 10.

The semiconductor device 100 may have one or more pads above the semiconductor substrate 10. The semiconductor device 100 in the present example has a gate pad 164. The semiconductor device 100 may have a pad such as an anode pad, a cathode pad, and a current detection pad. Each pad is arranged in a vicinity of the end side 162. The vicinity of the end side 162 refers to a region between the end side 162 and the emitter electrode in the top view. When the semiconductor device 100 is mounted, each pad may be connected to an external circuit via a wiring line such as a wire.

A gate potential is applied to the gate pad 164. The gate pad 164 is electrically connected to a conductive portion of a gate trench portion of the active portion 160. The semiconductor device 100 includes the gate runner that connects the gate pad 164 to the gate trench portion. In FIG. 1, the gate runner is hatched with diagonal lines.

The gate runner in the present example has an outer peripheral gate runner 130 and an active side gate runner 131. The outer peripheral gate runner 130 is arranged between the active portion 160 and the end side 162 of the semiconductor substrate 10 in the top view. The outer peripheral gate runner 130 in the present example encloses the active portion 160 in the top view. A region enclosed by the outer peripheral gate runner 130 in the top view may be set as the active portion 160. In addition, a well region is formed below the gate runner. The well region is a P type region having a higher concentration than that of the base region described below, and is formed from the upper surface of the semiconductor substrate 10 to a position deeper than that of the base region. A region enclosed by the well region in the top view may be set as the active portion 160.

The outer peripheral gate runner 130 is connected to the gate pad 164. The outer peripheral gate runner 130 is arranged above the semiconductor substrate 10. The outer peripheral gate runner 130 may be a metal wiring line containing aluminum or the like.

The active side gate runner 131 is provided in the active portion 160. Providing the active side gate runner 131 in the active portion 160 can reduce a variation in a wiring line length from the gate pad 164 for each region of the semiconductor substrate 10.

The outer peripheral gate runner 130 and the active side gate runner 131 are connected to the gate trench portion of the active portion 160. The outer peripheral gate runner 130 and the active side gate runner 131 are arranged above the semiconductor substrate 10. The outer peripheral gate runner 130 and the active side gate runner 131 may be a wiring line formed of a semiconductor such as polysilicon doped with an impurity.

The active side gate runner 131 may be connected to the outer peripheral gate runner 130. The active side gate runner 131 in the present example is provided to extend in the X axis direction so as to cross the active portion 160 substantially at the center of the Y axis direction from one outer peripheral gate runner 130 to another outer peripheral gate runner 130 which sandwich the active portion 160. When the active portion 160 is divided by the active side gate runner 131, the transistor portions 70 and the diode portions 80 may be alternately arranged in the X axis direction in each divided region.

The semiconductor device 100 may include a temperature sensing portion (not shown) that is a PN junction diode formed of polysilicon or the like, and a current detection portion (not shown) that simulates an operation of the transistor portion provided in the active portion 160.

The semiconductor device 100 in the present example includes an edge termination structure portion 190 between the active portion 160 and the end side 162 in the top view. The edge termination structure portion 190 in the present example is arranged between the outer peripheral gate runner 130 and the end side 162. The edge termination structure portion 190 reduces an electric field strength at the upper surface side of the semiconductor substrate 10. The edge termination structure portion 190 may include at least one of a guard ring, a field plate, or a RESURF which are annularly provided to enclose the active portion 160.

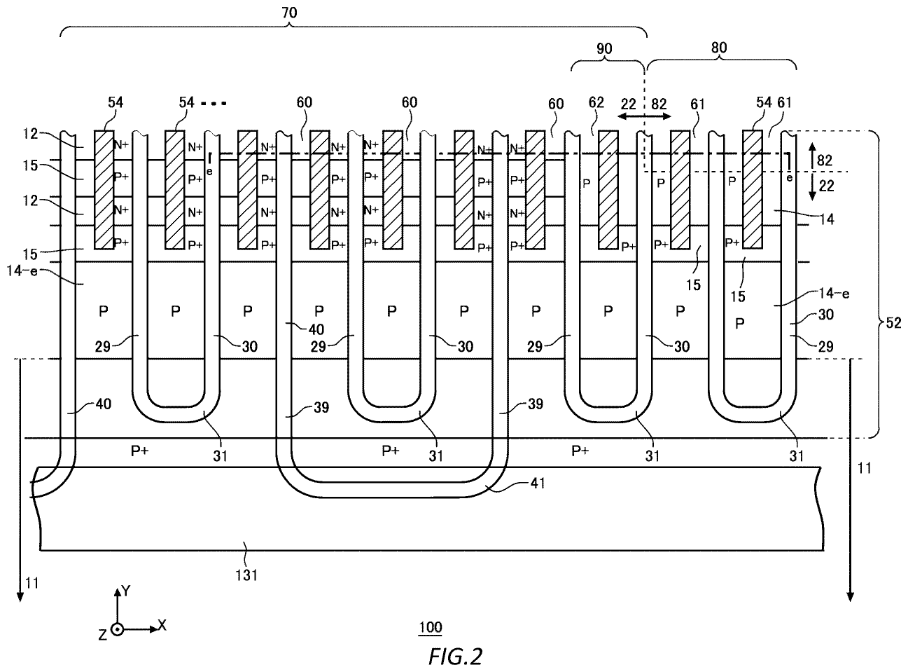

FIG. 2 shows an enlarged view of a region D in FIG. 1. The region D is a region including a transistor portion 70, a diode portion 80, and the active side gate runner 131. The semiconductor device 100 in the present example includes a gate trench portion 40, a dummy trench portion 30, a well region 11, an emitter region 12, a base region 14, and a contact region 15 which are provided inside the upper surface side of the semiconductor substrate 10. Each of the gate trench portion 40 and the dummy trench portions 30 is an example of the trench portion. In addition, the semiconductor device 100 in the present example includes an emitter electrode 52 and the active side gate runner 131 which are provided above the upper surface of the semiconductor substrate 10. The emitter electrode 52 and the active side gate runner 131 are provided to be separate from each other.

An interlayer dielectric film is provided between the emitter electrode 52 and the active side gate runner 131, and the upper surface of the semiconductor substrate 10; however, the interlayer dielectric film is omitted in FIG. 2. In the interlayer dielectric film in the present example, a contact portion 54 is provided to pass through the interlayer dielectric film. The contact portion 54 may have a contact hole provided in the interlayer dielectric film and a conductive member with which the contact hole is filled. In FIG. 2, each contact portion 54 is hatched with the diagonal lines.

The emitter electrode 52 is provided above the gate trench portion 40, the dummy trench portion 30, the well region 11, the emitter region 12, the base region 14, and the contact region 15. The emitter electrode 52 is connected to the emitter region 12, the contact region 15, and the base region 14 at the upper surface of the semiconductor substrate 10, through the contact portion 54. In addition, the emitter electrode 52 is connected to a dummy conductive portion in the dummy trench portion 30 through the contact hole provided in the interlayer dielectric film. The emitter electrode 52 may be connected to the dummy conductive portion of the dummy trench portion 30 at an edge of the dummy trench portion 30 in the Y axis direction.

The active side gate runner 131 is connected to the gate trench portion 40 through the contact hole provided in the interlayer dielectric film. The active side gate runner 131 may be connected to a gate conductive portion of the gate trench portion 40 at an edge portion 41 of the gate trench portion 40 in the Y axis direction. The active side gate runner 131 is not connected to the dummy conductive portion in the dummy trench portion 30.

The emitter electrode 52 is formed of a material containing metal. FIG. 2 shows a range where the emitter electrode 52 is provided. For example, at least a partial region of the emitter electrode 52 is formed of aluminum or an aluminum-silicon alloy, for example, a metal alloy such as AlSi or AlSiCu. The emitter electrode 52 may have a barrier metal formed of titanium, a titanium compound, or the like, below a region formed of aluminum or the like. Further, a plug, which is formed by embedding tungsten or the like so as to be in contact with the barrier metal and aluminum or the like, may be included in the contact hole.

The well region 11 is provided to overlap with the active side gate runner 131. The well region 11 is provided to extend with a predetermined width even in a range that does not overlap with the active side gate runner 131. The well region 11 in the present example is provided to be spaced apart from an end of the contact portion 54 in the Y axis direction toward the active side gate runner 131. The well region 11 is a region of a second conductivity type having a higher doping concentration than that of the base region 14. The base region 14 in the present example is of the P type, and the well region 11 is of the P+ type.

Each of the transistor portion 70 and the diode portion 80 has a plurality of trench portions arrayed in an array direction. In the transistor portion 70 in the present example, one or more gate trench portions 40 and one or more dummy trench portions 30 are alternately provided along the array direction. In the diode portion 80 in the present example, a plurality of dummy trench portions 30 are provided along the array direction. In the diode portion 80 in the present example, the gate trench portion 40 is not provided.

The gate trench portion 40 in the present example may have two linear parts 39 extending along the extension direction perpendicular to the array direction (parts of a trench which are linear along the extension direction), and the edge portion 41 connecting the two linear parts 39. The extension direction in FIG. 2 is the Y axis direction.

At least a part of the edge portion 41 is preferably provided in a curved shape in the top view. By the edge portion 41 connecting end portions of the two linear parts 39 in the Y axis direction, it is possible to reduce the electric field strength at the end portions of the linear parts 39.

In the transistor portion 70, the dummy trench portions 30 are provided between the respective linear parts 39 of the gate trench portions 40. Between the respective linear parts 39, one dummy trench portion 30 may be provided, or the plurality of dummy trench portions 30 may be provided. The dummy trench portion 30 may have a linear shape extending in the extension direction, or may have linear parts 29 and an edge portion 31 similarly to the gate trench portion 40.

A diffusion depth of the well region 11 may be deeper than depths of the gate trench portion 40 and the dummy trench portion 30. The end portions in the Y axis direction of the gate trench portion 40 and the dummy trench portion 30 are provided in the well region 11 in the top view. In other words, at the end portion of each trench portion in the Y axis direction, a bottom portion of each trench portion in the depth direction is covered with the well region 11. With this configuration, the electric field strength at the bottom portion of each trench portion can be reduced.

A mesa portion is provided between the respective trench portions in the array direction. The mesa portion refers to a region sandwiched between the trench portions inside the semiconductor substrate 10. As an example, an upper end of the mesa portion is the upper surface of the semiconductor substrate 10. A depth position of a lower end of the mesa portion is the same as a depth position of a lower end of the trench portion. The mesa portion in the present example is provided to extend in the extension direction (the Y axis direction) along the trench, at the upper surface of the semiconductor substrate 10.

In the present example, a mesa portion 60 is provided in the transistor portion 70, and a mesa portion 61 is provided in the diode portion 80. The transistor portion 70 in the present example has a boundary region 90. The boundary region 90 is an end portion of the transistor portion 70 in the X axis direction, and is in contact with the diode portion 80. The boundary region 90 is provided with a collector region 22 at a lower surface 23 of the semiconductor substrate 10. The boundary region 90 may include one or more trench portions. In the boundary region 90, the gate trench portion 40 may be provided, the dummy trench portion 30 may be provided, and both of the trench portions may be provided. A mesa portion 62 is provided in the boundary region 90. As merely referred to as the mesa portion in the present specification, it indicates each of the mesa portion 60, the mesa portion 61, and the mesa portion 62. The mesa portion 62 may have the same structure as that of the mesa portion 61. The boundary region 90 may be a region in which a structure at an upper surface 21 side is similar to that of the diode portion 80 and a structure at a lower surface 23 side is similar to that of the transistor portion 70. The transistor portion 70 may not have the boundary region 90. In this case, the mesa portion 60 of the transistor portion 70 and the mesa portion 61 of the diode portion 80 are arranged to be adjacent to each other at the boundary between the transistor portion 70 and the diode portion 80.

Each mesa portion is provided with the base region 14. In the mesa portion, a region arranged to be closest to the active side gate runner 131, in the base region 14 exposed to the upper surface of the semiconductor substrate 10, is set as a base region 14-e. While FIG. 2 shows the base region 14-e arranged at one end portion of each mesa portion in the extension direction, the base region 14-e is also arranged at another end portion of each mesa portion. Each mesa portion may be provided with at least one of the emitter region 12 of a first conductivity type, or the contact region 15 of the second conductivity type in a region sandwiched between the base regions 14-e in the top view. In the present example, the emitter region 12 is of the N+ type, and the contact region 15 is of the P+ type with a higher concentration than that of the base region 14. The emitter region 12 and the contact region 15 may be provided between the base region 14 and the upper surface of the semiconductor substrate 10 in the depth direction.

The mesa portion 60 of the transistor portion 70 has the emitter region 12 exposed to the upper surface of the semiconductor substrate 10. The emitter region 12 is provided in contact with the gate trench portion 40. The mesa portion 60 in contact with the gate trench portion 40 may be provided with the contact region 15 exposed to the upper surface of the semiconductor substrate 10.

The emitter region 12 in the mesa portion 60 is provided in contact with the gate trench portion 40. The emitter region 12 may be in contact with, or may not be in contact with the dummy trench portion 30. The emitter region 12 is also provided in a region which overlaps with the contact portion 54.

The contact region 15 in the mesa portion 60 is provided in the region which overlaps with the contact portion 54. The contact region 15 may be in contact with, or may not be in contact with the gate trench portion 40. The contact region 15 may be in contact with, or may not be in contact with the dummy trench portion 30.

In the example of FIG. 2, the emitter region 12 in the mesa portion 60 is provided from one trench portion in the X axis direction to another trench portion. The contact region 15 in the mesa portion 60 may also be provided from one trench portion in the X axis direction to another trench portion. The contact region 15 may not be in contact with either of two trench portions which sandwich the mesa portion 60. In this case, the base region 14 may be provided between the contact region 15 and the trench portion.

In the example of FIG. 2, the contact region 15 and the emitter region 12 in the mesa portion 60 are alternately arranged along the extension direction of the trench portion (the Y axis direction). In another example, the contact region 15 and the emitter region 12 in the mesa portion 60 may be provided in a stripe shape along the extension direction of the trench portion (the Y axis direction). For example, the emitter region 12 is provided in a region in contact with the trench portion, and the contact region 15 is provided in a region sandwiched between the emitter regions 12. In addition, the mesa portion 60 may be provided with the emitter region 12 instead of the contact region 15. For example, the emitter region 12 may be provided in an entire region sandwiched between the base regions 14-e in the Y axis direction.

The mesa portion 61 of the diode portion 80 is not provided with the emitter region 12. The base regions 14 and the contact regions 15 may be provided at an upper surface of the mesa portion 61. In the region sandwiched between the base regions 14-e at the upper surface of the mesa portion 61, the contact region 15 may be provided in contact with each of the base regions 14-e. The base region 14 may be provided in a region sandwiched between the contact regions 15 at the upper surface of the mesa portion 61. The base region 14 may be arranged in the entire region sandwiched between the contact regions 15. In the present example, the mesa portion 62 in the boundary region 90 has a structure similar to that of the mesa portion 61.

The contact portion 54 is provided above each mesa portion. The contact portion 54 is arranged in the region sandwiched between the base regions 14-e. The contact portion 54 in the present example is provided above each region of the contact region 15, the base region 14, and the emitter region 12. The contact portion 54 is not provided in regions corresponding to the base region 14-e and the well region 11. The contact portion 54 may be arranged at the center of the mesa portion 60 in the array direction (the X axis direction).

In the diode portion 80, a cathode region 82 of the N+ type is provided in a region adjacent to the lower surface of the semiconductor substrate 10. At the lower surface of the semiconductor substrate 10, the collector region 22 of the P+ type may be provided in a region where the cathode region 82 is not provided. The cathode region 82 and the collector region 22 are provided between the lower surface 23 of the semiconductor substrate 10 and a buffer region 20. In FIG. 2, a boundary between the cathode region 82 and the collector region 22 is indicated by a dotted line.

The cathode region 82 is arranged to be spaced apart from the well region 11 in the Y axis direction. With this configuration, the distance between a region of the P type (the well region 11) having a comparatively high doping concentration and formed up to the deep position, and the cathode region 82 is ensured, so that a breakdown voltage can be improved. An end portion of the cathode region 82 in the Y axis direction in the present example is arranged to be spaced apart from the well region 11 farther than an end portion of the contact portion 54 in the Y axis direction. In another example, the end portion of the cathode region 82 in the Y axis direction may be arranged between the well region 11 and the contact portion 54.

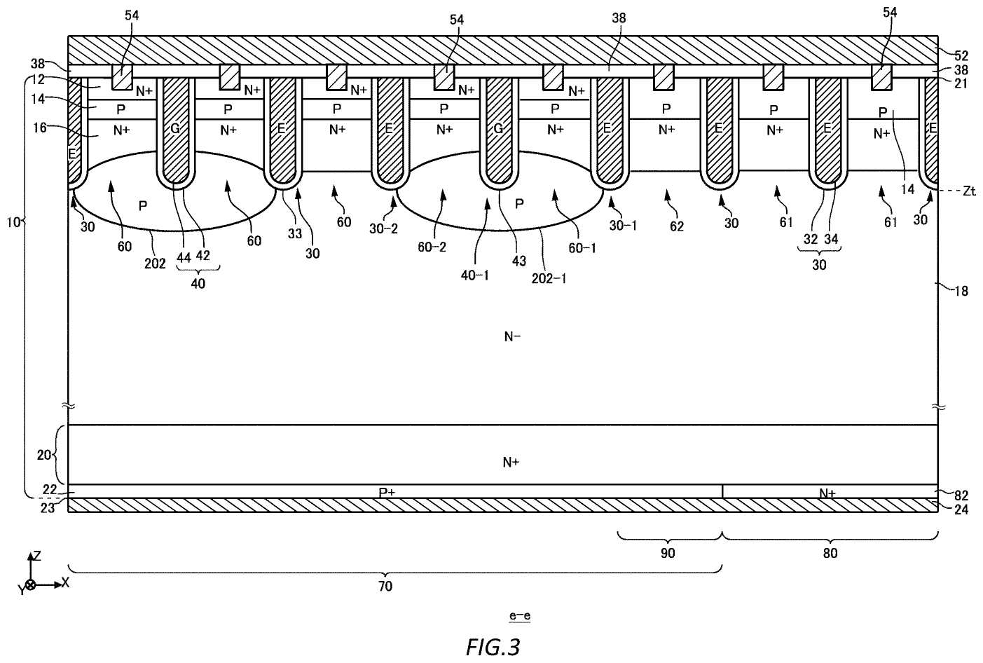

FIG. 3 is a view showing an example of a cross section e-e in FIG. 2. The cross section e-e is an XZ plane passing through an emitter region 12 and the cathode region 82. The semiconductor device 100 in the present example includes the semiconductor substrate 10, an interlayer dielectric film 38, the emitter electrode 52, and a collector electrode 24 in the cross section.

The interlayer dielectric film 38 is provided on the upper surface of the semiconductor substrate 10. The interlayer dielectric film 38 is a film including at least one layer of a dielectric film such as silicate glass to which an impurity such as boron or phosphorous is added, a thermal oxide film, or other dielectric films. The interlayer dielectric film 38 is provided with the contact portion 54 described with reference to FIG. 2.

The contact portion 54 is provided to pass through the interlayer dielectric film 38. The contact portion 54 may be formed of a metal different from that of the emitter electrode 52. The contact portion 54 may contain tungsten. A bottom portion of the contact portion 54 may be provided with a barrier metal layer containing at least one of a titanium film or a titanium nitride film. The contact portion 54 may be provided up to an upper surface 21 of the semiconductor substrate 10, or may be provided up to an inside of the semiconductor substrate 10. In the example of FIG. 3, the contact portion 54 is a contact trench provided from the upper surface 21 of the semiconductor substrate 10 to an inside of each mesa portion. This makes it possible to increase a contact area between the contact portion 54 and the semiconductor substrate 10. In the cross section, a lower end of the contact portion 54 of the transistor portion 70 is in contact with the emitter region 12. In the cross section, a lower end of the contact portion 54 of the diode portion 80 is in contact with the base region 14.

The emitter electrode 52 is provided above the interlayer dielectric film 38. The emitter electrode 52 is connected to the semiconductor substrate 10 via the contact portion 54. The collector electrode 24 is provided at the lower surface 23 of the semiconductor substrate 10. The emitter electrode 52 and the collector electrode 24 are formed of a metal material such as aluminum. In the present specification, a direction (the Z axis direction) in which the emitter electrode 52 is connected to the collector electrode 24 is referred to as the depth direction.

The semiconductor substrate 10 includes a drift region 18 of the N type or the N-type. The drift region 18 is provided in each of the transistor portion 70 and the diode portion 80.

In the mesa portion 60 of the transistor portion 70, the emitter region 12 of the N+ type and the base region 14 of the P type are provided in order starting from the upper surface 21 side of the semiconductor substrate 10. The drift region 18 is provided below the base region 14. The mesa portion 60 may be provided with an accumulation region 16 of the N+ type. The accumulation region 16 is arranged between the base region 14 and the drift region 18.

The emitter region 12 is exposed to the upper surface 21 of the semiconductor substrate 10 and is provided in contact with the gate trench portion 40. The emitter region 12 may be in contact with the trench portions on both sides of the mesa portion 60. The emitter region 12 has a higher doping concentration than that of the drift region 18.

The base region 14 is provided below the emitter region 12. The base region 14 in the present example is provided in contact with the emitter region 12. The base region 14 may be in contact with the trench portions on both sides of the mesa portion 60.

The accumulation region 16 is provided below the base region 14. The accumulation region 16 is a region of the N+ type having a higher doping concentration than that of the drift region 18. That is, the accumulation region 16 has a higher donor concentration than that of the drift region 18. Providing the accumulation region 16 having a high concentration between the drift region 18 and the base region 14 can increase a carrier injection enhancement effect (IE effect) and reduce an on-voltage. The accumulation region 16 may be provided so as to cover an entire lower surface of the base region 14 in each mesa portion 60.

In the mesa portion 61 of the diode portion 80, the base region 14 of the P type is provided in contact with the upper surface 21 of the semiconductor substrate 10. The drift region 18 is provided below the base region 14. In the mesa portion 61, the accumulation region 16 may be provided below the base region 14.

In the mesa portion 62 of the boundary region 90, the base region 14 of the P type is provided in contact with the upper surface 21 of the semiconductor substrate 10. The drift region 18 is provided below the base region 14. In the mesa portion 62, the accumulation region 16 may be provided below the base region 14. The mesa portion 62 in the present example has a structure similar to that of the mesa portion 61. In each example in the present specification, the center of the trench portion in the X axis direction may be set as an end portion of the boundary region 90 in the X axis direction.

In each of the transistor portion 70 and the diode portion 80, the buffer region 20 of the N+ type may be provided below the drift region 18. A doping concentration of the buffer region 20 is higher than the doping concentration of the drift region 18. The buffer region 20 may have a concentration peak having a higher doping concentration than that of the drift region 18. A doping concentration at a concentration peak refers to a doping concentration at a local maximum of the concentration peak. In addition, as the doping concentration of the drift region 18, an average value of doping concentrations in a region where a doping concentration distribution is substantially flat may be used.

The buffer region 20 may have two or more concentration peaks in the depth direction (the Z axis direction) of the semiconductor substrate 10. The concentration peak of the buffer region 20 may be provided, for example, at the same depth position as that of a chemical concentration peak of hydrogen (a proton) or phosphorous. The buffer region 20 may function as a field stopper layer which prevents a depletion layer expanding from a lower end of the base region 14 from reaching the collector region 22 of the P+ type and the cathode region 82 of the N+ type.

In the transistor portion 70, the collector region 22 of the P+ type is provided below the buffer region 20. An acceptor concentration of the collector region 22 is higher than an acceptor concentration of the base region 14. The collector region 22 may include an acceptor which is the same as or different from an acceptor of the base region 14. The acceptor of the collector region 22 is, for example, boron.

Below the buffer region 20 in the diode portion 80, the cathode region 82 of the N+ type is provided. A donor concentration of the cathode region 82 is higher than a donor concentration of the drift region 18. A donor of the cathode region 82 is, for example, hydrogen or phosphorous. It should be noted that an element serving as a donor and an acceptor in each region is not limited to the example described above. The collector region 22 and the cathode region 82 are exposed to the lower surface 23 of the semiconductor substrate 10 and are connected to the collector electrode 24

The collector electrode 24 may be in contact with the entire lower surface 23 of the semiconductor substrate 10. The emitter electrode 52 and the collector electrode 24 are formed of a metal material such as aluminum.

One or more gate trench portions 40 and one or more dummy trench portions 30 are provided at the upper surface 21 side of the semiconductor substrate 10. Each trench portion passes through the base region 14, and is provided from the upper surface 21 of the semiconductor substrate 10 to a region below the base region 14. In a region where at least any of the emitter region 12, the contact region 15, or the accumulation region 16 is provided, each trench portion also passes through the doping regions of these. A structure in which the trench portion passes through the doping region is not limited to a structure which is made by forming the doping region and then forming the trench portion in order. A structure in which the trench portion is formed and then the doping region is formed between the trench portions is also included in the structure in which the trench portion passes through the doping region.

As described above, the transistor portion 70 is provided with the gate trench portion 40 and the dummy trench portion 30. The diode portion 80 is provided with the dummy trench portion 30, and is not provided with the gate trench portion 40. A boundary between the diode portion 80 and the transistor portion 70 in the X axis direction, in the present example, is a boundary between the cathode region 82 and the collector region 22.

The boundary region 90 in the present example is provided with the dummy trench portion 30, and is not provided with the gate trench portion 40. The trench portion at the end portion of the boundary region 90 on a transistor portion 70 side may be the gate trench portion 40.

The gate trench portion 40 includes a gate trench provided in the upper surface 21 of the semiconductor substrate 10, a gate dielectric film 42, and a gate conductive portion 44. The gate dielectric film 42 is provided to cover an inner wall of the gate trench. The gate dielectric film 42 may be formed by oxidizing or nitriding a semiconductor at the inner wall of the gate trench. The gate conductive portion 44 is provided farther inward than the gate dielectric film 42 inside the gate trench. In other words, the gate dielectric film 42 insulates the gate conductive portion 44 from the semiconductor substrate 10. The gate conductive portion 44 is formed of a conductive material such as polysilicon.

The gate conductive portion 44 may be provided to be longer than the base region 14 in the depth direction. The gate trench portion 40 in the cross section is covered by the interlayer dielectric film 38 on the upper surface 21 of the semiconductor substrate 10. The gate conductive portion 44 is electrically connected to the gate runner. When a predetermined gate voltage is applied to the gate conductive portion 44, a channel is formed by an electron inversion layer in a surface layer of the base region 14 at a boundary in contact with the gate trench portion 40.

The dummy trench portions 30 may have the same structure as that of the gate trench portions 40 in the cross section. The dummy trench portion 30 includes a dummy trench provided in the upper surface 21 of the semiconductor substrate 10, a dummy dielectric film 32, and a dummy conductive portion 34. The dummy conductive portion 34 is electrically connected to the emitter electrode 52. The dummy dielectric film 32 is provided to cover an inner wall of the dummy trench. The dummy conductive portion 34 is provided inside the dummy trench, and is provided farther inward than the dummy dielectric film 32. The dummy dielectric film 32 insulates the dummy conductive portion 34 from the semiconductor substrate 10. The dummy conductive portion 34 may be formed of the same material as that of the gate conductive portion 44. For example, the dummy conductive portion 34 is formed of a conductive material such as polysilicon. The dummy conductive portion 34 may have the same length as that of the gate conductive portion 44 in the depth direction.

The gate trench portion 40 and the dummy trench portion 30 in the present example are covered with the interlayer dielectric film 38 on the upper surface 21 of the semiconductor substrate 10. It should be noted that bottom portions of the dummy trench portion 30 and the gate trench portion 40 may have curved surfaces which are convex downward (curved shapes in the cross sections). In the present specification, a depth position of a lower end 43 of the gate trench portion 40 is set as Zt.

The semiconductor device 100 in the present example includes a floating region 202 of the P type provided below the lower end 43 of the gate trench portion 40. The lower end 43 of the gate trench portion 40 refers to a part, in the gate trench portion 40, which is closest to the lower surface 23 of the semiconductor substrate 10. In the example of FIG. 3, the lower end 43 of the gate trench portion 40 is arranged at the center of the gate trench portion 40 in the X axis direction. In addition, a lower end 33 of the dummy trench portion 30 refers to a part, in the dummy trench portion 30, which is closest to the lower surface 23 of the semiconductor substrate 10. In the example of FIG. 3, the lower end 33 of the dummy trench portion 30 is arranged at the center of the dummy trench portion 30 in the X axis direction.

At least a part of the floating region 202 is provided at a position that overlaps with the lower end 43 in the top view, and is arranged below the lower end 43 in the Z axis direction. The floating region 202 may include a part that does not overlap with the lower end 43 in the top view. The floating region 202 may include a part provided above the lower end 43. The floating region 202 may be in contact with the lower end 43, or may be spaced apart from the lower end 43. In the example of FIG. 3, the floating region 202 is in contact with the entire curved surface part including the lower end 43, in the gate trench portion 40. The floating region 202 may be formed, after forming a trench structure of the gate trench portion 40 and before forming the gate conductive portion 44, by implanting the dopant of the P type in a vicinity of a lower end of the trench structure.

The floating region 202 is electrically floating with respect to an electrode of metal, or polysilicon, or the like. At least one of a region of the N type or a dielectric film is arranged between the floating region 202 and the electrode. In other words, the floating region 202 and the electrode are not connected to each other by a region of the P type or a conductive material. A doping concentration of the floating region 202 may be lower than or equal to the doping concentration of the base region 14, or may be higher than the doping concentration of the base region 14. The doping concentration of the floating region 202 in the present example is higher than the doping concentration of the base region 14. The doping concentration may be higher than or equal to 1×10¹⁵ cm⁻³ and lower than or equal to 1×10¹⁷ cm⁻³.

The floating region 202 is arranged to be spaced apart from the base region 14. A region of the N type (in the present example, at least one of the accumulation region 16 or the drift region 18) is provided between the floating region 202 and the base region 14.

Each transistor portion 70 has one or more floating regions 202. Each transistor portion 70 may have a plurality of floating regions 202. In each transistor portion 70, the floating region 202 may be provided in at least one gate trench portion 40, the floating region 202 may be provided in 50% or more of the gate trench portions 40, the floating region 202 may be provided in 80% or more of the gate trench portions 40, or the floating region 202 may be provided in all of the gate trench portions 40.

In at least one transistor portion 70, the floating region 202 is provided in the gate trench portion 40 which is closest to the diode portion 80. In a plurality of transistor portions 70, the floating region 202 may be provided in the gate trench portion 40 which is closest to the diode portion 80. In all of the transistor portions 70, the floating region 202 may be provided in the gate trench portion 40 which is closest to the diode portion 80.

In the present specification, among one or more gate trench portions 40 in the transistor portion 70, the one that is provided to be closest to the diode portion 80 in a first direction is set as a first gate trench portion 40-1. Among one or more dummy trench portions 30 in the transistor portion 70, those arranged to be adjacent to the first gate trench portion 40-1 are set as a first dummy trench portion 30-1 and a second dummy trench portion 30-2. The first dummy trench portion 30-1 is arranged outside the first gate trench portion 40-1. In other words, the first dummy trench portion 30-1 is arranged between the first gate trench portion 40-1 and the diode portion 80. In the present example, the first dummy trench portion 30-1 is arranged at the end portion of the boundary region 90. The second dummy trench portion 30-2 is arranged inside the first gate trench portion 40-1. In other words, the second dummy trench portion 30-2 is arranged on an opposite side of the first gate trench portion 40-1 from the first dummy trench portion 30-1.

Among a plurality of mesa portions 60, the one that is in contact with the first gate trench portion 40-1 and that is provided between the first gate trench portion 40-1 and the diode portion 80 is set as a first mesa portion 60-1. The first mesa portion 60-1 is the mesa portion 60 sandwiched between the first gate trench portion 40-1 and the first dummy trench portion 30-1.

The mesa portion 60 which is in contact with the first gate trench portion 40-1 and is arranged on an opposite side of the first gate trench portion 40-1 from the first mesa portion 60-1 is set as a second mesa portion 60-2. The second mesa portion 60-2 is the mesa portion 60 sandwiched between the first gate trench portion 40-1 and the second dummy trench portion 30-2.

Among one or more floating regions 202, the one provided below the first gate trench portion 40-1 is set as a first floating region 202-1. Each floating region 202 may extend to, or may not extend to, a region below the lower end 33 of the trench portion (the dummy trench portion 30 in the present example) arranged to be adjacent to the corresponding gate trench portion 40. Each floating region 202 may be in contact with, or may not be in contact with, the trench portion adjacent to the gate trench portion 40. In the present example, each floating region 202 does not extend in the X axis direction to a position beyond the trench portion adjacent to the gate trench portion 40. Each floating region 202 does not extend below the mesa portion 60 which is not in contact with the gate trench portion 40.

FIG. 3 shows the first gate trench portion 40-1, the first floating region 202-1, the first mesa portion 60-1, and the second mesa portion 60-2, which are provided at one end portion of the transistor portion 70 in the X axis direction. When the transistor portion 70 is sandwiched between two diode portions 80, the transistor portion 70 is provided with the first gate trench portion 40-1, the first floating region 202-1, the first mesa portion 60-1, and the second mesa portion 60-2, at each end portion on both sides in the X axis direction.

The lower end 33 of each dummy trench portion 30 may be in contact with a region of the N type (in the present example, the drift region 18). In the present example, at the upper surface 21 side of the semiconductor substrate 10, below the lower end 33, no region of the P type is provided, and a region of the N type (the drift region 18 in the present example) is provided.

By providing the floating region 202, it is possible to prevent electrons from flowing to the lower end 43 of the first gate trench portion 40-1 when the transistor portion 70 is turned on, and to cause a depletion layer to remain in a vicinity of the lower end 43. This makes it possible to reduce a reverse recovery dV/dt. The reverse recovery dV/dt is a slope of a time waveform of an anode-cathode voltage at a time of the reverse recovery of the diode portion 80. In addition, when the semiconductor device 100 is used in a circuit such as a three-phase inverter, it is possible to decrease a tail of a voltage waveform of the IGBT provided in opposing arms. Therefore, it is possible to improve a trade-off characteristic between a turn-on loss and the reverse recovery dV/dt.

On the other hand, in the semiconductor device 100 in which the transistor portion 70 and the diode portion 80 are provided side by side, some of the electrons injected from the emitter region 12 of the transistor portion 70 flow into the cathode region 82 of the diode portion 80. Therefore, it becomes difficult to raise a potential of a PN junction at an end portion of the collector region 22 of the transistor portion 70, and a snapback may occur when the transistor portion 70 is turned on. When the floating region 202 is provided, an electron current from the emitter region 12 is hindered, and thus it becomes further difficult to raise the potential of the PN junction at the end portion of the collector region 22, which makes the snapback likely to occur.

In the present example, the first mesa portion 60-1 arranged in a vicinity of the diode portion 80 is provided with an uncovered region which does not overlap with the first floating region 202-1. This makes it possible for the electrons from the first mesa portion 60-1 to flow more easily, thereby suppressing the snapback. In other words, it is possible to suppress the snapback while also improving the trade-off characteristic described above.

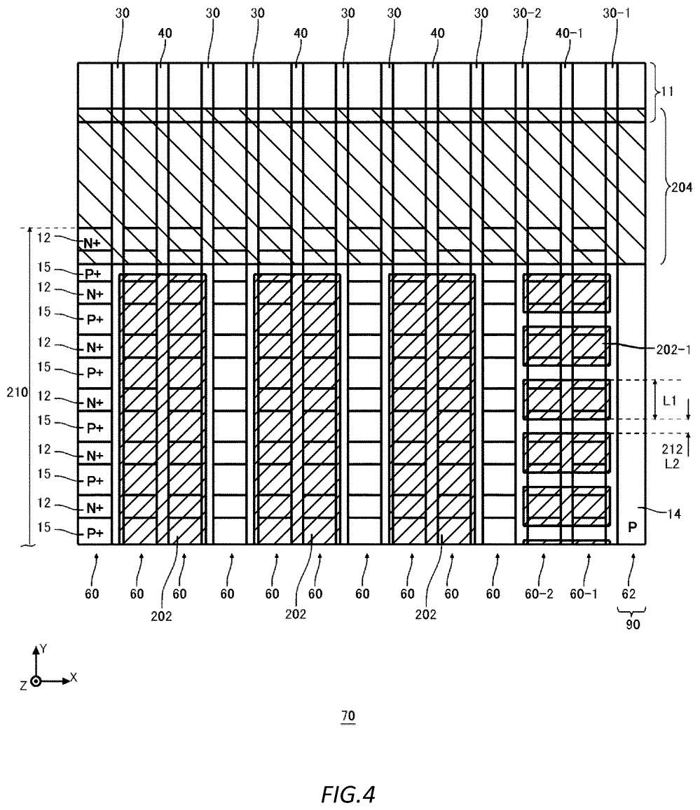

FIG. 4 is a diagram showing an arrangement example of the floating region 202 in a top view. FIG. 4 shows an enlarged view of the transistor portion 70 in a vicinity of the boundary region 90. In addition, FIG. 4 shows the well region 11 arranged outside the emitter region 12 in the Y axis direction. Above the well region 11, the outer peripheral gate runner 130 described with reference to FIG. 1 extends in the X axis direction.

In at least one transistor portion 70, the first mesa portion 60-1 has an uncovered region 212 which does not overlap with the first floating region 202-1. The uncovered region 212 may be provided in the first mesa portion 60-1 in the plurality of transistor portions 70, or the uncovered region 212 may be provided in the first mesa portion 60-1 in all of the transistor portions 70. The uncovered region 212 in the present example is provided over the entire first mesa portion 60-1 in the X axis direction.

Each mesa portion 60 has a longitudinal length in the Y axis direction. The extension direction of the longest straight line among end sides of the mesa portion 60 in the top view, may be set as a longitudinal direction of the mesa portion 60. In each mesa portion 60, a region between both ends of the emitter region 12 in the Y axis direction, is set as an intermediate region 210. In the mesa portion 60 in the present example, the emitter regions 12 are arranged discretely in the Y axis direction. In this case, outer end portions of the two emitter regions 12 arranged at both ends in the Y axis direction are set as both ends of the intermediate region 210. In the mesa portion 60, the emitter regions 12 and the contact regions 15 may be alternately arranged in the Y axis direction.

The uncovered region 212 may be provided in the intermediate region 210 of the first mesa portion 60-1. In the present example, a plurality of first floating regions 202-1 are arranged discretely along the Y axis in the intermediate region 210 of the first mesa portion 60-1. In addition, a plurality of uncovered regions 212 are also arranged discretely along the Y axis in the intermediate region 210 of the first mesa portion 60-1. This makes it possible for the electrons from the first mesa portion 60-1 to flow easily, thereby suppressing the snapback.

The first floating region 202-1 may overlap with, or may be spaced apart from the first dummy trench portion 30-1, in the top view. When the first floating region 202-1 is spaced apart from the first dummy trench portion 30-1, it is possible to further suppress the snapback.

In the intermediate region 210 of the first mesa portion 60-1, a total sum of lengths L2 of the plurality of uncovered regions 212 in the Y axis direction, may be smaller than a total sum of lengths L1 of regions, in the Y axis direction, which overlap with the first floating region 202-1. This makes it easy to improve the trade-off characteristic between the turn-on loss and the reverse recovery dV/dt. The total sum of the lengths L2 may be 70% or less of the total sum of the lengths L1, or may be 50% or less. The total sum of the lengths L2 may be 10% or more of the total sum of the lengths L1, may be 30% or more, or may be 50% or more.

The total sum of the lengths L2 may be greater than the total sum of the lengths L1. This makes it easy to suppress the snapback. The total sum of the lengths L2 may be 1.3 times or more of the total sum of the lengths L1, may be 1.5 times or more, or may be two times or more. The total sum of the lengths L2 may be 10 times or less of the total sum of the lengths L1, or may be three times or less, or may be two times or less.

The uncovered region 212 may be provided also in the intermediate region 210 of the second mesa portion 60-2. The arrangement of the first floating region 202-1 of the second mesa portion 60-2 and the uncovered region 212, in the Y axis direction, may be similar to that of the first mesa portion 60-1. The first floating region 202-1 in the second mesa portion 60-2 may overlap with, or may be spaced apart from the second dummy trench portion 30-2, in the top view. As an example, the first floating region 202-1 may overlap with the second dummy trench portion 30-2, and may be spaced apart from the first dummy trench portion 30-1.

In the present example, the first floating region 202-1 is arranged below at least one emitter region 12 of the first mesa portion 60-1. The first floating region 202-1 may overlap the entirety of the corresponding emitter region 12. The first floating region 202-1 may be arranged below a plurality of emitter regions 12. The first floating regions 202-1 may be arranged for all of the emitter regions 12, except for the emitter regions 12 arranged at both ends in the Y axis direction. In addition, the first floating regions 202-1 may be arranged for all of the emitter regions 12, including the emitter regions 12 arranged at both ends in the Y axis direction. By providing the first floating region 202-1 to overlap with the emitter region 12, it becomes easy to improve the trade-off characteristic between the turn-on loss and the reverse recovery dV/dt.

In the present example, at least a part of the contact region 15 is the uncovered region 212. Each contact region 15 may be provided with the uncovered region 212. In each contact region 15, a part in contact with the emitter region 12 may overlap with the first floating region 202-1. Each contact region 15 may not overlap with the first floating region 202-1.

In another example, the first floating region 202-1 may be arranged below at least one contact region 15 of the first mesa portion 60-1. The first floating regions 202-1 may be arranged below a plurality of contact regions 15. The first floating regions 202-1 may be arranged for all of the contact regions 15, except for the contact regions 15 arranged at both ends in the Y axis direction. In addition, the first floating regions 202-1 may be arranged for all of the contact regions 15, including the contact regions 15 arranged at both ends in the Y axis direction.

In this case, at least a part of the emitter region 12 is the uncovered region 212. Each emitter region 12 may be provided with the uncovered region 212. In each emitter region 12, a part in contact with the contact region 15 may overlap with the first floating region 202-1. Each emitter region 12 may not overlap with the first floating region 202-1. By providing the first floating region 202-1 to overlap with the contact region 15, the electrons further flow easily, which makes it easy to suppress the snapback.

In the mesa portions 60 other than the first mesa portion 60-1 and the second mesa portion 60-2, one floating region 202 may be provided for each mesa portion 60. A length of the floating region 202 of the mesa portion 60 in the Y axis direction is greater than the length L1 of one of the first floating regions 202-1 in the Y axis direction. The length of the floating region 202 in the present example is equal to a sum of the total sum of the lengths L1 and the total sum of the lengths L2. In the present example, positions of both ends of the floating region 202 in the Y axis direction are the same as positions of the outer end portions of the first floating region 202-1 arranged at both ends in the Y axis direction. The length of the floating region 202 in the Y axis direction may be 50% or more of a length of the linear part 39 of the gate trench portion 40 in the Y axis direction, may be 70% or more, or may be 90% or more.

An area (referred to as a first area) of the uncovered region 212 in the first mesa portion 60-1 in the top view, may be greater than an area (referred to as a second area) of a region which does not overlap with the floating region 202 in the mesa portion 60 in contact with the gate trench portion 40 other than the first gate trench portion 40-1. The first area is a value obtained by multiplying a width of the first mesa portion 60-1 in the X axis direction by the total sum of the lengths L2. The second area is a value obtained by multiplying a width of the mesa portion 60 in the X axis direction by a total sum of lengths of regions, in the Y axis direction, which do not overlap with the floating region 202. The second area may be zero.

As shown in FIG. 4, a first extension region 204 may be provided to extend from the well region 11 to a position that overlaps with the emitter region 12. The first extension region 204 is a region of the P type. The first extension region 204 is connected to the well region 11. The well region 11 is connected to the emitter electrode 52. The first extension region 204 may be provided at the same depth position as that of the floating region 202. The first extension region 204 may have the same doping concentration as that of the floating region 202. The first extension region 204 is separate from the floating region 202.

The first extension region 204 in the present example overlaps with the entire emitter region 12 which is closest to the well region 11. The first extension region 204 may not overlap with the emitter region 12 which is second closest to the well region 11. By providing the first extension region 204, it is possible to set, to an emitter potential, a region from the well region 11 to a region below the outermost emitter region 12. This makes it possible to set an electric field distribution to be uniform in a region where the first extension region 204 is provided, thereby suppressing a decrease in the breakdown voltage. The first extension region 204 may be provided over the entire transistor portion 70 in the X axis direction. The first extension region 204 may be provided over the entire diode portion 80 in the X axis direction.

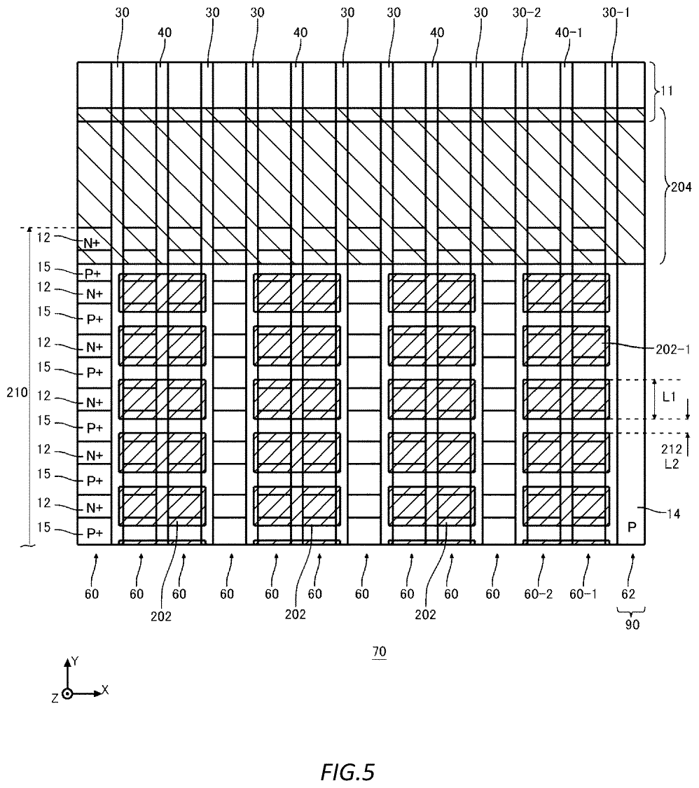

FIG. 5 is a diagram showing another arrangement example of the floating region 202 in the top view. The arrangement of the first floating region 202-1 is similar to that in the example of FIG. 4. In the present example, the floating regions 202 other than the first floating region 202-1 are also arranged discretely in the Y axis direction, similarly to the first floating region 202-1. In the present example, the length of the floating region 202 in the Y axis direction other than the first floating region 202-1 may be the same as the length L1 of the first floating region 202-1. An interval in the Y axis direction between the floating regions 202 other than the first floating region 202-1 may be the same as an interval L2 between the first floating regions 202-1.

At least one of the floating regions 202 other than the first floating region 202-1 may be arranged discretely in the Y axis direction. For example, the floating regions 202 adjacent to the first floating region 202-1 may be arranged discretely in the Y axis direction. The other floating regions 202 may be arranged continuously in the Y axis direction, similarly to the example of FIG. 4. As shown in FIG. 5, all of the floating regions 202 may be arranged discretely in the Y axis direction.

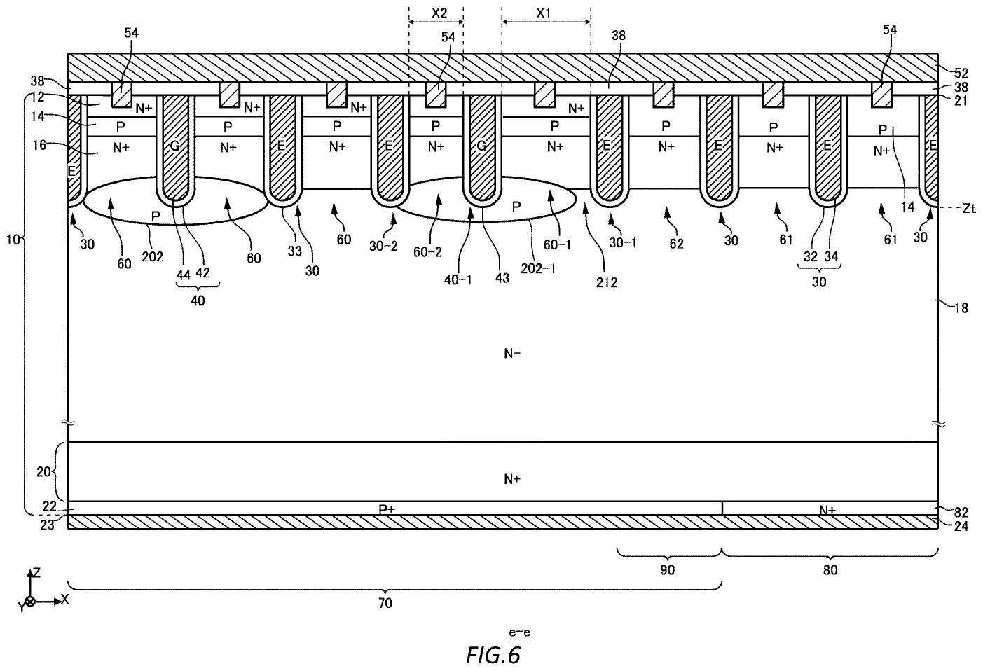

FIG. 6 is a view showing another example of the cross section e-e. The present example is different from the example described with reference to FIG. 3 in the arrangement of the first floating region 202-1. The other structures may be similar to any of the examples described with reference to FIG. 3 to FIG. 5.

The first floating region 202-1 in the present example does not extend in the X axis direction to a region below the lower end 33 of the first dummy trench portion 30-1. The first floating region 202-1 is not in contact with the first dummy trench portion 30-1 in the top view. The uncovered region 212 is provided between the first floating region 202-1 and the first dummy trench portion 30-1. The first floating region 202-1 may extend to, or may not extend to a region below the contact portion 54 of the first mesa portion 60-1. The first floating region 202-1 may extend to, or may not extend to the center of the first mesa portion 60-1 in the X axis direction.

The first floating region 202-1 may be arranged discretely in the Y axis direction, similarly to the first floating region 202-1 in FIG. 4 and FIG. 5. In another example, the first floating region 202-1 may be provided continuously as a single region in the Y axis direction, similarly to the floating region 202 in FIG. 4. Even in this case, the uncovered region 212 is provided between the first dummy trench portion 30-1 and the first floating region 202, and thus it is possible to suppress the snapback.

A width of the first mesa portion 60-1 in the X axis direction is set as X1. A width of the uncovered region 212 in the X axis direction may be 10% or more of the width X1, may be 20% or more, or may be 30% or more. The width of the uncovered region 212 in the X axis direction may be 90% or less of the width X1, may be 80% or less, or may be 70% or less. As shown in FIG. 6, the width of the uncovered region 212 in the X axis direction may be 50% or less of the width X1.

The first floating region 202-1 may be in contact with the second dummy trench portion 30-2 in the top view. In the present example, the first floating region 202-1 is in contact with the second dummy trench portion 30-2 in the XZ cross section.

A width of the second mesa portion 60-2 in the X axis direction is set as X2. The width X2 may be smaller than the width X1. In other words, the first gate trench portion 40-1 is arranged to be biased toward a direction of the second dummy trench portion 30-2, between the first dummy trench portion 30-1 and the second dummy trench portion 30-2. With such a configuration, when the dopant of the P type is implanted and diffused via the trench structure of the first gate trench portion 40-1 to form the first floating region 202-1, it becomes easy to cause the first floating region 202-1 to be spaced apart from the first dummy trench portion 30-1 and to be brought into contact with the second dummy trench portion 30-2.

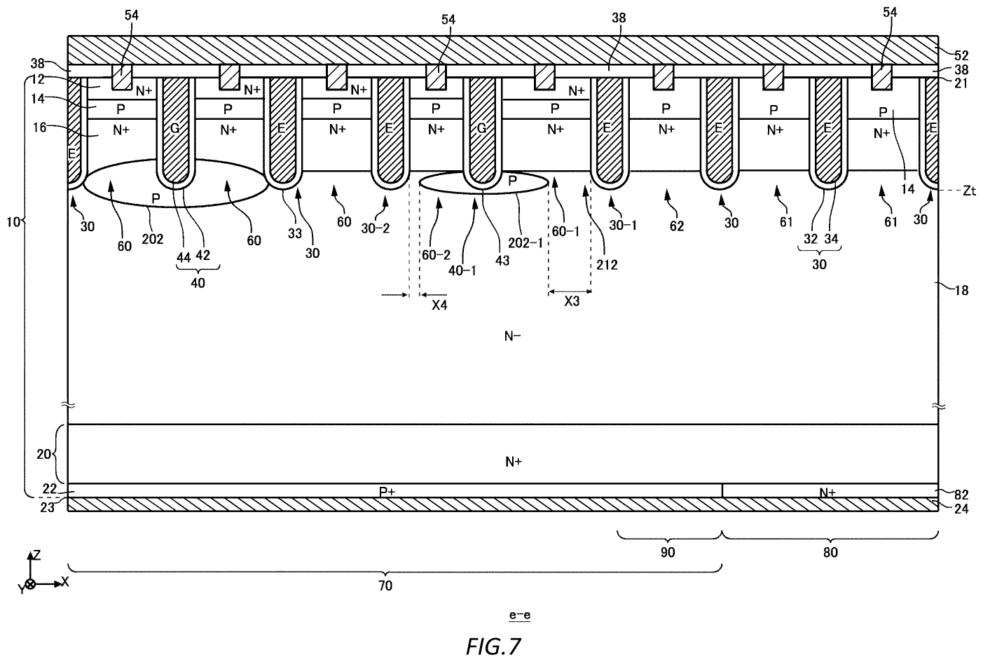

FIG. 7 is a view showing another example of the cross section e-e. The present example is different from the example described with reference to FIG. 6 in the arrangement of the first floating region 202-1. The other structures may be similar to any of the examples described with reference to FIG. 6.

The first floating region 202-1 in the present example is arranged to be spaced apart from the second dummy trench portion 30-2, as well, in the top view. In the X axis direction, a distance between the first floating region 202-1 and the first dummy trench portion 30-1 is set as X3, and a distance between the first floating region 202-1 and the second dummy trench portion 30-2 is set as X4. The distance X4 may be smaller than the distance X3. The distance X4 may be 50% or less of the distance X3, or may be 30% or less. The distance X4 may be zero as in the example of FIG. 6. In the present example, it is also possible to suppress the snapback.

The floating regions 202 other than the first floating region 202-1 may be similar to the example of FIG. 6. In another example, all of the floating regions 202 may have a structure similar to the first floating region 202-1 of FIG. 7.

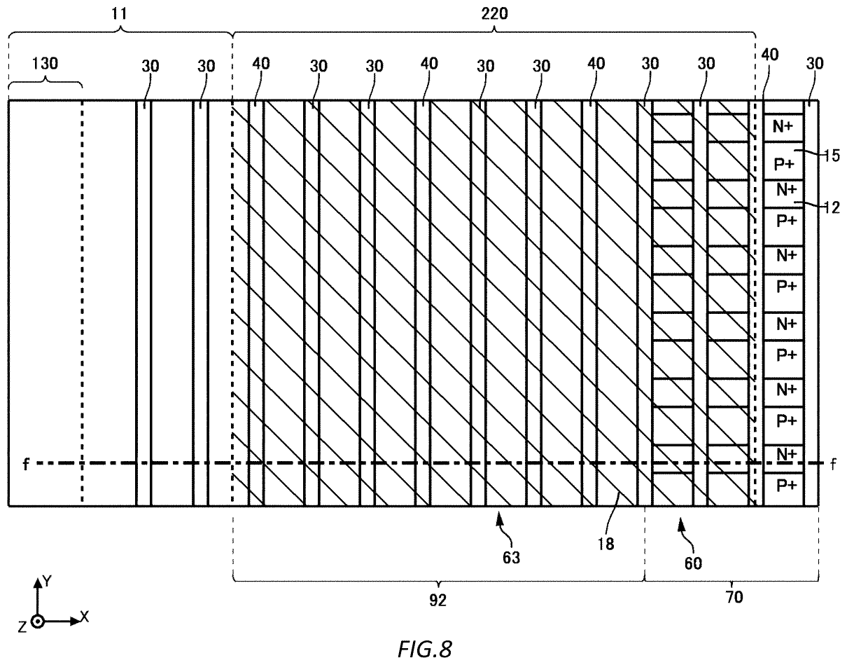

FIG. 8 is a top plan view showing an example of a transition region 92. A structure of the transition region 92 which is described with reference to FIG. 8 may be combined with any of the examples which is described in the present specification. The structure of the transition region 92 which is described with reference to FIG. 8 may be combined with the structure of the floating region 202 in any example which is described in the present specification. In another example, the floating region 202 in the semiconductor device 100 which is described with reference to FIG. 8 may have a structure different from those in the examples from FIG. 1 to FIG. 7. Alternatively, the semiconductor device 100 which is described with reference to FIG. 8 may not have the floating region 202. The semiconductor device 100 which is described with reference to FIG. 8 may not include the diode portion 80.

In the present example, the well region 11 is arranged also outside the emitter region 12 in the X axis direction. In the present example, the outer peripheral gate runner 130 extending in the Y axis direction is arranged above the well region 11.

The transition region 92 is arranged between the emitter region 12 (or the transistor portion 70) and the well region 11, in the X axis direction. The transition region 92 has one or more trench portions arranged side by side in the X axis direction. The transition region 92 may have one or more dummy trench portions 30, may have one or more gate trench portions 40, or may have both of the dummy trench portion 30 and gate trench portion 40. The transition region 92 in the present example has trench portions of an array pattern similar to that of the transistor portion 70. In the transistor portion 70 in the present example, one gate trench portion 40 and two dummy trench portions 30 are alternately arranged. In the transition region 92 as well, one gate trench portion 40 and two dummy trench portions 30 may be alternately arranged.

In the well region 11 as well, one or more trench portions may be arranged. In the present example, two dummy trench portions 30 are arranged inside the well region 11.

The transition region 92 may have the collector region 22 at a position in contact with the lower surface 23. The transition region 92 may have the cathode region 82 at a position in contact with the lower surface 23. The transition region 92 includes one or more mesa portions 63. The drift region 18 may be exposed to the upper surface 21 of the mesa portion 63. In another example, the base region 14 may be provided at the upper surface 21 of the mesa portion 63.

The semiconductor device 100 in the present example includes a second extension region 220 provided in the transition region 92. The second extension region 220 is a region of the P type which extends in the X axis direction from the well region 11 to a position that overlaps with the emitter region 12. The second extension region 220 is connected to the well region 11. The second extension region 220 may be provided at the same depth position as that of the floating region 202. The second extension region 220 may have the same doping concentration as that of the floating region 202.

The second extension region 220 in the present example overlaps with the entire emitter region 12 of the mesa portion 60 which is closest to the well region 11 in the X axis direction. The second extension region 220 may overlap with the entire emitter regions 12 of two or more mesa portions 60 which are closest to the well region 11. When the contact region 15 is provided in the mesa portion 60, the second extension region 220 overlaps with the contact region 15, as well. The second extension region 220 is not connected to the floating region 202.

By providing the second extension region 220, it is possible to set the transition region 92 to the emitter potential. This makes it possible to set the electric field distribution to be uniform in the transition region 92, thereby suppressing a decrease in the breakdown voltage. The second extension region 220 may be provided in a range wider than the floating region 202, in the Y axis direction. The second extension region 220 may be connected to the first extension region 204 described with reference to FIG. 4 or the like, at an end portion in the Y axis direction.

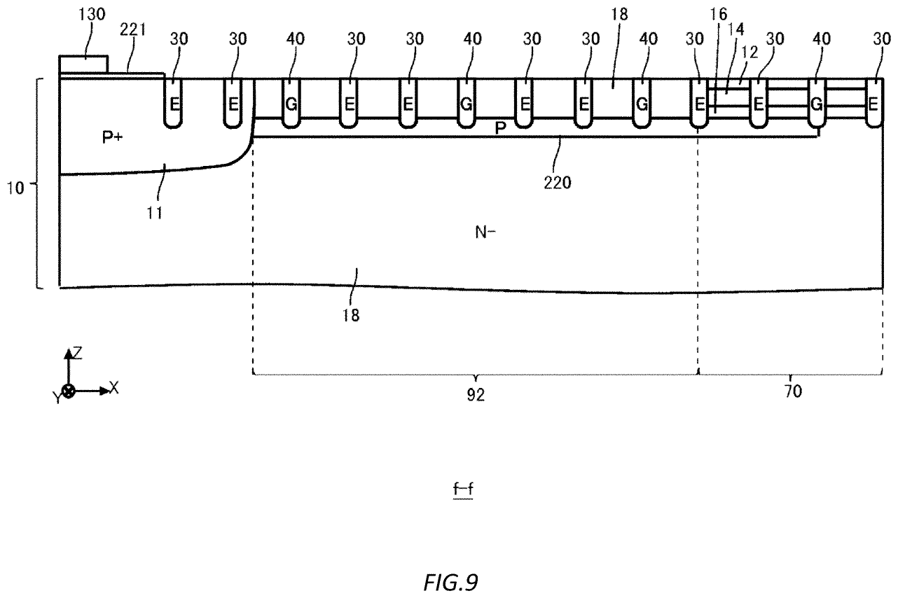

FIG. 9 is a view showing an example of a cross section f-f in FIG. 8. The cross section f-f is the XZ plane including the well region 11, the transition region 92, and the transistor portion 70. As described above, the outer peripheral gate runner 130 is arranged above the well region 11. The outer peripheral gate runner 130 and the well region 11 are insulated from each other by a dielectric film 221 such as an oxide film. In FIG. 9, the structures of the upper surface side such as the emitter electrode 52 and the interlayer dielectric film 38, and the structure of the lower surface side such as the collector electrode 24 are omitted.

The second extension region 220 is provided below the lower ends of one or more trench portions provided in the transition region 92. The second extension region 220 may be in contact with the lower end of each trench portion. The second extension region 220 extends in the X axis direction to the transistor portion 70, beyond the transition region 92.

The second extension region 220 extends to a region below the emitter region 12. The second extension region 220 may extend to a region below the lower end of at least one gate trench portion 40 of the transistor portion 70. Below the gate trench portion 40, the floating region 202 is not provided. By providing the second extension region 220, it is possible to set the electric field distribution to be uniform in the transition region 92, thereby suppressing a decrease in the breakdown voltage.

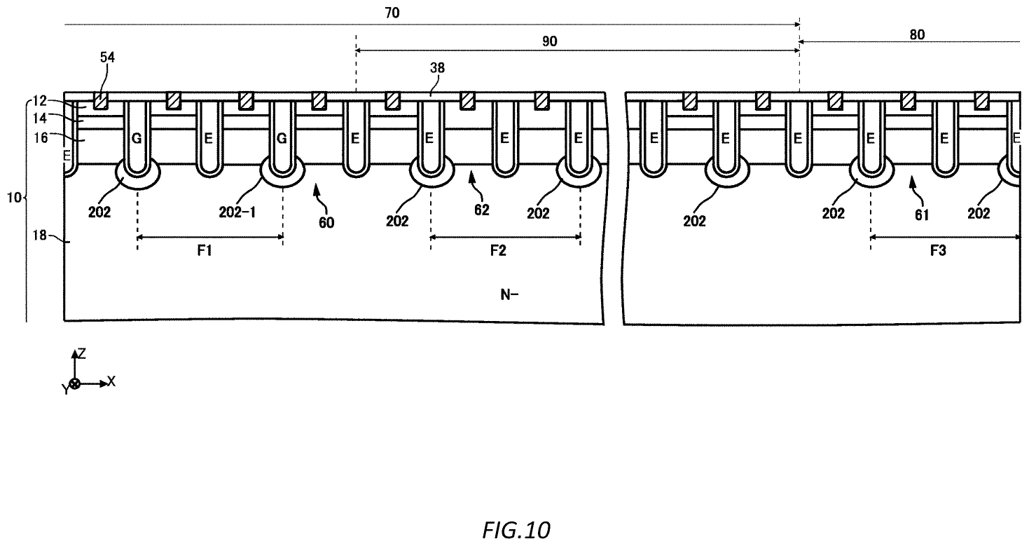

FIG. 10 is an XZ cross section showing another structure example of the boundary region 90 and the diode portion 80. In FIG. 10, the structures of the upper surface side such as the emitter electrode 52 and the interlayer dielectric film 38, and the structure of the lower surface side such as the collector electrode 24 are omitted.

In the example described with reference to FIG. 1 to FIG. 9, the boundary region 90 and the diode portion 80 are not provided with the floating region 202. In the present example, at least one of the boundary region 90 or the diode portion 80 is provided with the floating region 202. The structure described with reference to FIG. 10 can be applied to any of the examples described with reference to FIG. 1 to FIG. 9. By providing the floating region 202 in the boundary region 90, it is possible to set the electric field distributions to be uniform in the transistor portion 70 other than the boundary region 90, and the boundary region 90. By providing the floating region 202 in the diode portion 80, it is possible to set the electric field distributions to be uniform in the transistor portion 70 and the diode portion 80.

In the example of FIG. 10, the array pattern of the trench portions in the transistor portion 70 is different from that in the example of FIG. 3 or the like. In the example of FIG. 10, one gate trench portion 40 and one dummy trench portion 30 are alternately arranged in the X axis direction. The array pattern of the trench portions in the transistor portion 70 may be either of the pattern in FIG. 3 or FIG. 10, or may be another pattern. In the transistor portion 70 in the present example, each gate trench portion 40 is provided with the floating region 202.

The floating region 202 in the example of FIG. 10 does not extend to a position that overlaps with the trench portion (the dummy trench portion 30 in the present example) arranged to be adjacent to the corresponding gate trench portion 40. As described with reference to FIG. 3 to FIG. 9, the floating region 202 may extend to a position that overlaps with at least one trench portion arranged to be adjacent to the gate trench portion 40.

In the example of FIG. 10, the boundary region 90 has the plurality of dummy trench portions 30, a plurality of mesa portions 62, and one or more floating regions 202. The floating region 202 is provided below the lower end of at least one trench portion of the boundary region 90. A period F2 in which the floating region 202 is provided in the X axis direction in the boundary region 90, may be the same as a period F1 in which the floating region 202 is provided in the X axis direction in the transistor portion 70 other than the boundary region 90. By setting the periods, in which the floating regions 202 are provided, to be the same as each other, it is further possible to set the electric field distribution to be uniform. The period in which the floating region 202 is provided is a distance between the center positions of the respective floating regions 202 in the X axis direction.

In the example of FIG. 10, the floating region 202 is also provided below the lower end of at least one trench portion of the diode portion 80. A period F3 in which the floating region 202 is provided in the X axis direction in the diode portion 80, may be the same as the period F1 in the transistor portion 70. By setting the periods, in which the floating regions 202 are provided, to be the same as each other, it is further possible to set the electric field distribution to be uniform.

In the boundary region 90, in the Y axis direction, the plurality of floating regions 202 may be arranged discretely, or the floating region 202 may be provided continuously as a single region. In the diode portion 80, in the Y axis direction, the plurality of floating regions 202 may be arranged discretely, or the floating region 202 may be provided continuously as a single region.

The periods F1, F2 and F3 of the floating regions 202 may not be the same. The period F1 may be greater than, or may be smaller than the period F2. The period F1 may be greater than, or may be smaller than the period F3. The period F3 may be greater than, or may be smaller than the period F2. By adjusting the periods F1 to F3, it is possible to adjust breakdown voltage distributions of the transistor portion 70, the boundary region 90, and the diode portion 80. For example, when the period F1 is set to be great, it is possible to lower the breakdown voltage of the transistor portion 70, and to relatively raise the breakdown voltage of the diode portion 80. Conversely, by setting the period F3 to be great, it is possible to lower the breakdown voltage of the diode portion 80, and to relatively raise the breakdown voltage of the transistor portion 70. In addition, the periods F1 to F3 may be adjusted such that the breakdown voltages of the transistor portion 70, the boundary region 90, and the diode portion 80 are the same as one another.

Intervals between all of the trench portions in the semiconductor device 100 in the X axis direction may be the same as each other. In another example, the intervals between the trench portions in the X axis direction may not be uniform.

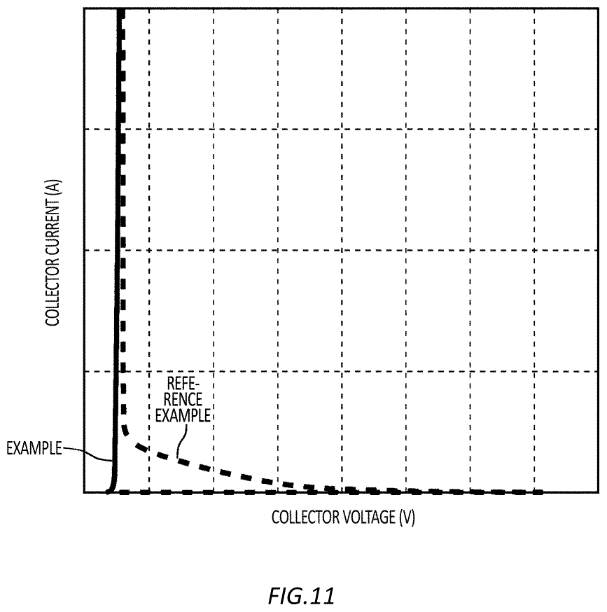

FIG. 11 is a diagram showing a collector voltage-collector current characteristic, in an Example and a reference example. The reference example is an example in which the uncovered region 212 is not provided in the first mesa portion 60-1. The Example is an example in which the uncovered region 212 is provided in the first mesa portion 60-1.

In the reference example, the floating region 202 makes it difficult for the electron current of the first mesa portion 60-1 to flow to the collector region 22. Therefore, in the reference example, as shown in FIG. 11, there occurs the snapback in which almost no collector current flows until the collector voltage becomes greater than a predetermined voltage. In contrast with this, in the semiconductor device 100 according to the Example, the electron current of the first mesa portion 60-1 easily flows to the collector region 22. Therefore, the snapback does not occur.

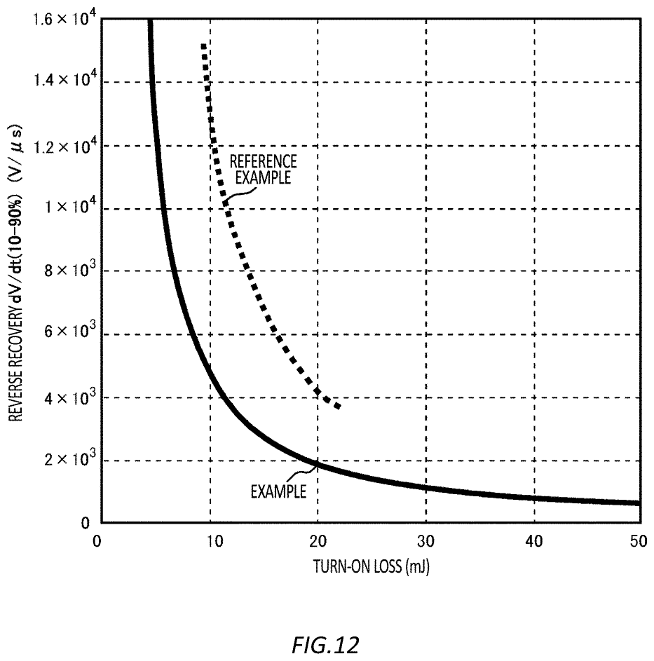

FIG. 12 is a diagram showing a trade-off characteristic between a turn-on loss and a reverse recovery dV/dt in a reference example and an Example. FIG. 12 shows the trade-off relationship in which the turn-on loss is increased when the reverse recovery dV/dt is reduced.

The reference example in FIG. 12 is a semiconductor device which does not have the floating region 202. The semiconductor device of the Example is the semiconductor device 100 described with reference to FIG. 1 to FIG. 10. The semiconductor device 100 of the Example has the floating region 202, thereby improving the trade-off characteristic. For example, when the reverse recovery dV/dt is set to be the same, the turn-on loss is smaller in the Example than in the reference example.

As described with reference to FIG. 12, with the semiconductor device 100, it is possible to improve the trade-off characteristic between the turn-on loss and the reverse recovery dV/dt. As described with reference to FIG. 11, with the semiconductor device 100, it is possible to suppress the snapback.

While the present invention has been described by way of the embodiments, the technical scope of the present invention is not limited to the above-described embodiments. It is apparent to persons skilled in the art that various alterations or improvements can be made to the above described embodiments. It is also apparent from the described scope of the claims that the embodiments added with such alterations or improvements can be included the technical scope of the present invention.

The operations, procedures, steps, stages, or the like of each process performed by a device, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” for convenience in the claims, embodiments, or diagrams, it does not necessarily mean that the process must be performed in this order.

What is claimed is:

1. A semiconductor device comprising:
a semiconductor substrate which has an upper surface and a lower surface, and which has a drift region of a first conductivity type;
one or more transistor portions which are provided with a collector region of a second conductivity type at the lower surface of the semiconductor substrate; and
one or more diode portions which are provided with a cathode region of the first conductivity type at the lower surface of the semiconductor substrate, and which are arranged alternately with the transistor portions in a first direction, wherein
each of the transistor portions has
a plurality of trench portions which are provided side by side in the first direction, and which include one or more gate trench portions,
a plurality of mesa portions which are regions sandwiched between the trench portions in the first direction, and
a floating region of the second conductivity type which is provided for at least one of the gate trench portions, and which is provided below a lower end of the gate trench portion,
the one or more gate trench portions include a first gate trench portion which is provided to be closest to the diode portion,
the plurality of mesa portions include a first mesa portion which is in contact with the first gate trench portion, and which is provided between the first gate trench portion and the diode portion,
below the first gate trench portion, a first floating region is provided, and
the first mesa portion has an uncovered region which does not overlap with the first floating region.

2. The semiconductor device according to claim 1, wherein
the plurality of trench portions include one or more dummy trench portions,
the first mesa portion is sandwiched between the first gate trench portion and a first dummy trench portion, and
the first floating region does not extend to a region below a lower end of the first dummy trench portion.

3. The semiconductor device according to claim 2, wherein
the first floating region is not in contact with the first dummy trench portion in a top view.

4. The semiconductor device according to claim 3, wherein
the plurality of trench portions include a second dummy trench portion which is arranged on an opposite side of the first gate trench portion from the first dummy trench portion, and
in the first direction, a distance between the first floating region and the second dummy trench portion is smaller than a distance between the first floating region and the first dummy trench portion.

5. The semiconductor device according to claim 4, wherein
the first floating region is in contact with the second dummy trench portion in the top view.

6. The semiconductor device according to claim 1, wherein
the first mesa portion has
an emitter region of the first conductivity type which is provided in contact with the upper surface of the semiconductor substrate, and
a base region of the second conductivity type which is provided between the emitter region and the drift region,
the first mesa portion has a longitudinal length in a second direction, and
the first mesa portion has the uncovered region, in an intermediate region between both ends of the emitter region in the second direction.

7. The semiconductor device according to claim 6, wherein
in the intermediate region, a plurality of uncovered regions, each of which is the uncovered region, are arranged discretely in the second direction.

8. The semiconductor device according to claim 7, wherein
in the intermediate region, a total sum of lengths of the plurality of uncovered regions in the second direction, is smaller than a total sum of lengths of regions, in the second direction, which overlap with the first floating region.

9. The semiconductor device according to claim 7, wherein
the first mesa portion has a contact region of the second conductivity type which is provided in contact with the upper surface of the semiconductor substrate, and which is arranged alternately with the emitter region in the second direction, and
the first floating region is arranged below at least one of emitter regions, each of which is the emitter region, and at least a part of the contact region is the uncovered region.

10. The semiconductor device according to claim 9, wherein
the first floating region overlaps the entirety of at least one of the emitter regions, and
each of contact regions, which is the contact region, is provided with the uncovered region.

11. The semiconductor device according to claim 6, further comprising:
a well region of the second conductivity type which is arranged outside the first mesa portion in the second direction, and which has a higher concentration than that of the base region; and
a first extension region of the second conductivity type which extends in the second direction from the well region to a position that overlaps with the emitter region.

12. The semiconductor device according to claim 6, further comprising:
a well region of the second conductivity type which is arranged outside the emitter region in the first direction, and which has a higher concentration than that of the base region; and
a second extension region of the second conductivity type which extends in the first direction from the well region to a position that overlaps with the emitter region.

13. The semiconductor device according to claim 1, wherein
the diode portion has
a plurality of dummy trench portions which are provided side by side in the first direction, and
a mesa portion which is sandwiched between the dummy trench portions in the first direction, and
the floating region is also provided below a lower end of at least one of the dummy trench portions of the diode portion.

14. The semiconductor device according to claim 13, wherein
a period in which the floating region is provided in the first direction in the diode portion, is the same as a period in which the floating region is provided in the first direction in the transistor portion.

15. The semiconductor device according to claim 1, wherein
the transistor portion has a boundary region which has one or more of the trench portions and one or more of the mesa portions, between the first gate trench portion and the diode portion, and
the floating region is also provided below a lower end of at least one of the trench portions of the boundary region.

16. The semiconductor device according to claim 15, wherein
a period in which the floating region is provided in the first direction in the boundary region, is the same as a period in which the floating region is provided in the first direction in the transistor portion other than the boundary region.

17. The semiconductor device according to claim 1, wherein
an area of the uncovered region in the first mesa portion is greater than an area of a region which does not overlap with the floating region in the mesa portion in contact with the gate trench portion other than the first gate trench portion.

18. The semiconductor device according to claim 1, wherein
the plurality of mesa portions have a base region of the second conductivity type which is provided between the upper surface of the semiconductor substrate and the drift region, and
a doping concentration of the floating region is higher than a doping concentration of the base region.

19. The semiconductor device according to claim 2, wherein
the plurality of trench portions include a second dummy trench portion which is arranged on an opposite side of the first gate trench portion from the first dummy trench portion, and
the first floating region does not extend to a region below a lower end of the second dummy trench portion.

20. The semiconductor device according to claim 11, wherein
the first extension region is provided at a same depth position as that of the floating region.

21. The semiconductor device according to claim 12, wherein
the second extension region is provided at a same depth position as that of the floating region.

22. The semiconductor device according to claim 2, wherein
the plurality of trench portions include
a second dummy trench portion which is arranged on an opposite side of the first gate trench portion from the first dummy trench portion, and
a third dummy trench portion which is arranged on an opposite side of the second dummy trench portion from the first gate trench portion, and
the first floating region is in contact with the second dummy trench portion, and is not in contact with the third dummy trench portion, in a top view.
